(19) United States
(12) Patent Application Publication
(10) Pub. No.: US 2009/0126789 A1
(43) Pub. Date: May 21, 2009

(54) Dye-sensitized solar cell

(75) Inventors: Chung-Hua Li, Taipei City (TW); Hung-Chieh Tsai, Tainan City (TW)

Correspondence Address: BACON & THOMAS, PLLC, 625 SLATERS LANE, FOURTH FLOOR, ALEXANDRIA, VA, 22314-1176, US

(73) Assignee: Aurotek Corporation, Taipei (TW)

(21) Appl. No.: 12/289,541

(22) Filed: Oct. 30, 2008

(30) Foreign Application Priority Data
Oct. 30, 2007 (TW) 096140766

(51) Int. Cl. H01L 31/00

(52) U.S. Cl. 136/256

(57) ABSTRACT

The present invention relates to a dye-sensitized solar cell that exhibits improved photoabsorption efficiency and optoelectronic conversion efficiency in the long-wavelength region. The dye-sensitized solar cell of the present invention, in coordination with an outer loop, comprises: a first substrate; a second substrate; and a photoenergy conversion layer disposed between the first substrate and the second substrate. Herein, the photoenergy conversion layer comprises an electrolytic condensed matter and pluralities of dye-adsorbed units dispersed in the electrolytic condensed matter. In addition, a first photonic crystal layer is disposed on the surface of the first substrate. A beam of light from the external environment can pass through the first photonic crystal layer and the first substrate to arrive in the photoenergy conversion layer. The photoenergy conversion layer can convert the photoenergy of the light to electric energy and the outer loop electrically connects to the first substrate and the second substrate.

### BACKGROUND OF THE INVENTION

1. Field of the Invention

The present invention relates to a dye-sensitized solar cell and, more particularly, to a dye-sensitized solar cell that exhibits improved photoabsorption efficiency and optoelectronic conversion efficiency in the long-wavelength region.

2. Description of Related Art

Since the various finite energy sources (such as uranium, natural gas, petroleum and so on) on which people rely will be exhausted before long, large amounts of money and effort are being spent to develop the application of alternative energy (i.e. “green energy”), such as solar energy, wind power, wave power and terrestrial heat. However, among the above-mentioned various kinds of green energy, the applications of wind power, wave power and terrestrial heat are restricted to specific areas, such as volcano areas or seaboards. In addition, the equipment for the employment of the aforementioned energy is in large-scale, such as windmills, deep seawater intake pipes, and so on, resulting in the restriction on the application of the green energy.

On the contrary, solar energy can be applied in any area that can be illuminated by sunshine. Thereby, the solar energy industry is viewed as a most favorable industry, and thereby great amounts of resources are committed to develop solar cells and the related devices. However, the development of silicon solar cells faces a bottleneck, due to the insufficient production and high cost of silicon that is the main material used in a solar cell, the high cost of machinery for manufacturing solar cells, low speed of mass production for solar cells, and the difficulty in improving optoelectronic conversion efficiency of solar cells.

In view of the above-mentioned situation, another type of solar cell, dye-sensitized solar cells (DSSC), has been developed to enhance the absorption of visible-light through dyestuffs attached on the wide band-gap semiconductor materials so as to convert photoenergy into electric energy.

A conventional dye-sensitized solar cell is illustrated in FIG. 1, comprising: a first substrate 11, a second substrate 12 and a photoenergy conversion layer 13 disposed between the first substrate 11 and the second substrate 12. Herein, the photoenergy conversion layer 13 comprises an electrolytic condensed matter 131 and pluralities of dye-adsorbed units 132, and the dye-adsorbed units 132 are dispersed in the electrolytic condensed matter 131. In addition, the conventional solar cell is operated in coordination with an outer loop 10, and the first substrate 11 and the second substrate 12 electrically connect to the outer loop 10. Furthermore, the electrolytic condensed matter 131 of the photoenergy conversion layer 13 comprises pluralities of redox mediators, and the dye-adsorbed units 132 comprise pluralities of titanium oxide nanocapsules. In the conventional dye-sensitized solar cell, a first transparent conductor 14 is disposed on a side of the first substrate 11 adjacent to the photoenergy conversion layer 13, and the first transparent conductor 14 electrically connects to the aforementioned outer loop 10. The second transparent conductor 15 is disposed on a side of the second substrate 12 adjacent to the photoenergy conversion layer 13, and the second transparent conductor 15 electrically connects to the aforementioned outer loop 10.

During the operation of the conventional dye-sensitized solar cell, a beam of light from the external environment passes through the first substrate 11 and the first transparent conductor 14, and arrives in the photoenergy conversion layer 13. However, the light may pass through the second transparent conductor 15 and the second substrate 12 to leave the conventional dye-sensitized solar cell. Alternatively, the light is reflected from the dye-adsorbed units 132, and then passes through the first transparent conductor 14 and the first substrate 11 to leave the conventional dye-sensitized solar cell. Thereby, the conventional dye-sensitized solar cell cannot thoroughly convert photoenergy into electric energy, so that the optoelectronic conversion efficiency of the conventional dye-sensitized solar cell cannot be further enhanced.

In addition, with reference to FIG. 2, there is shown a photoabsorption efficiency-wavelength diagram of each component in the conventional dye-sensitized solar cell. The curve A represents the correlation between photoabsorption efficiency of the titanium oxide nanocapsules in the photoenergy conversion layer and wavelength. The curve B represents the correlation between photoabsorption efficiency of the first dyestuff RuL₃ in the photoenergy conversion layer and wavelength. The curve C represents the correlation between photoabsorption efficiency of the second dyestuff RuL′(NCS)₃ in the photoenergy conversion layer and wavelength.

As shown in FIG. 2, the absorption of the titanium oxide nanocapsules in the photoenergy conversion layer is maximized at the wavelength less than 400 nm (curve A); and the absorption of the first dyestuff RuL₃ and the second dyestuff RuL′(NCS)₃ in the photoenergy conversion layer is maximized in the range of from 400 nm to 800 nm (curves B and C). That is, the light with the wavelength larger than 800 nm cannot be efficiently absorbed by the conventional dye-sensitized solar cell and thus cannot be converted into electric energy. Thereby, in the long-wavelength region (larger than 800 nm), the optoelectronic conversion efficiency of the conventional dye-sensitized solar cell cannot be efficiently enhanced.

Accordingly, there is an unfulfilled need for a dye-sensitized solar cell with improved absorption efficiency and optoelectronic conversion efficiency in the long-wavelength range.

### SUMMARY OF THE INVENTION

The object of the present invention is to provide a dye-sensitized solar cell that exhibits improved photoabsorption efficiency in the long wavelength range.

Another object of the present invention is to provide a dye-sensitized solar cell that has improved optoelectronic conversion efficiency.

To achieve the object, the dye-sensitized solar cell of the present invention, in coordination with an outer loop, comprises: a first substrate, a second substrate, and a photoenergy conversion layer disposed between the first substrate and the second substrate. Herein, the photoenergy conversion layer comprises an electrolytic condensed matter and pluralities of dye-adsorbed units, and the dye-adsorbed units are dispersed in the electrolytic condensed matter. In the present invention, a first photonic crystal layer is disposed on the surface of the first substrate. A beam of light from the external environment can pass through the first photonic crystal layer and the first substrate to arrive in the photoenergy conversion layer. The photoenergy conversion layer can convert the photoenergy of the light to electric energy. The outer loop electrically connects to the first substrate and the second substrate.

Accordingly, the dye-sensitized solar cell of the present embodiment can convert the photoenergy of the long-wavelengthed light to electric energy by the photonic crystal layers (such as the first and second photonic crystal layers) disposed therein. That is, the dye-sensitized solar cell of the present embodiment can efficiently employ the photoenergy of light that cannot be employed in a conventional dye-sensitized solar cell, such as an infrared ray. Thereby, in the long-wavelength range, the dye-sensitized solar cell of the present embodiment has improved absorption efficiency and optoelectronic conversion efficiency so as to replace a current silicon solar cell and be a future most favored technology in the green energy industries.

In the dye-sensitized solar cell of the present invention, the first photonic crystal layer can be formed on the surface of the first substrate by any method. Preferably, the first photonic crystal layer is formed on the surface of the first substrate by an etching process for definition of a nanocapsule array, a process for stacking one or pluralities of nanocapsule layers on the surface of the first substrate, a nano-imprinting process, or a photography process. Herein, the nanocapsules used in the aforementioned etching process for definition of a nanocapsule array can be made of any material. Preferably, the nanocapsules are made of silicon oxide, polymethyl methacrylate or polystyrene. In addition, the first photonic crystal layer of the present invention can be in any type. Preferably, the first photonic crystal layer consists of one nanocapsule layer, pluralities of nanocapsule layers, pluralities of photoresist units, or pluralities of spherical hollow portions. The pluralities of nanocapsules in the nanocapsule layer(s) can be made of any material. Preferably, the material of the nanocapsules is silicon oxide, silicon, polymethyl methacrylate, polystyrene, or titanium oxide. The pluralities of photoresist units can be in any structure. Preferably, the photoresist units are in the shape of a cylinder, an elliptic cylinder, or an oblong pillar. The pluralities of spherical hollow portions can be in any shape. Preferably, the spherical hollow portions are in the shape of a sphere or an ellipse.

In the dye-sensitized solar cell of the present invention, the second photonic crystal layer can be formed on the surface of the second substrate by any method. Preferably, the second photonic crystal layer is formed on the surface of the second substrate by an etching process for definition of a nanocapsule array, a process for stacking one or pluralities of nanocapsule layers on the surface of the second substrate, a nano-imprinting process, or a photography process. In addition, the second photonic crystal layer of the present invention can be in any type. Preferably, the second photonic crystal layer is a distributed Bragg reflector or consists of one nanocapsule layer or pluralities of nanocapsule layers. The pluralities of nanocapsules in the nanocapsule layer(s) can be made of any material. Preferably, the material of the nanocapsules is silicon oxide, silicon, polymethyl methacrylate, polystyrene, or titanium oxide.

In the dye-sensitized solar cell of the present invention, the first substrate can be made of any material. Preferably, the first substrate is made of glass, polyethylene terephthalate, polyethylene naphthalate, polyethyl sulfone or polycarbonate. In the dye-sensitized solar cell of the present invention, the second substrate can be made of any material. Preferably, the second substrate is made of glass, polyethylene terephthalate, polyethylene naphthalate, polyethyl sulfone or polycarbonate. In the dye-sensitized solar cell of the present invention, the first transparent conductor can be made of any material. Preferably, the first transparent conductor is made of indium tin oxide, indium zinc oxide, zinc aluminum oxide, or zinc gallium oxide. In the dye-sensitized solar cell of the present invention, the second transparent conductor can be made of any material. Preferably, the second transparent conductor is made of indium tin oxide, indium zinc oxide, zinc aluminum oxide, or zinc gallium oxide.

Other objects, advantages, and novel features of the invention will become more apparent from the following detailed description when taken in conjunction with the accompanying drawings.

### BRIEF DESCRIPTION OF THE DRAWINGS

FIG. 1 is a perspective view of a conventional dye-sensitized solar cell;

FIG. 2 is a photoabsorption efficiency-wavelength diagram of each component in a conventional dye-sensitized solar cell;

FIG. 3 is a perspective view of a dye-sensitized solar cell in a first preferred embodiment of the present invention;

FIG. 4 is a perspective view of an etching process for definition a nanocapsule array to form a first photonic crystal layer on the surface of a first substrate of a first preferred embodiment of the present invention;

FIGS. 5A to 5B are a perspective view of a process for stacking nanocapsules to form a second photonic crystal layer on the surface of a second substrate of a first preferred embodiment of the present invention;

FIG. 6 is a photoabsorption efficiency-wavelength diagram of each component in a dye-sensitized solar cell of a first preferred embodiment;

FIG. 7 is a perspective view of a dye-sensitized solar cell in a second preferred embodiment of the present invention; and

FIG. 8 is a perspective view of a dye-sensitized solar cell in a third preferred embodiment of the present invention.

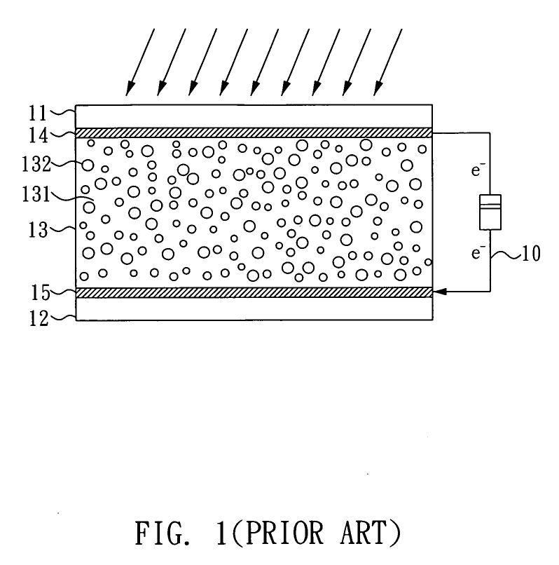

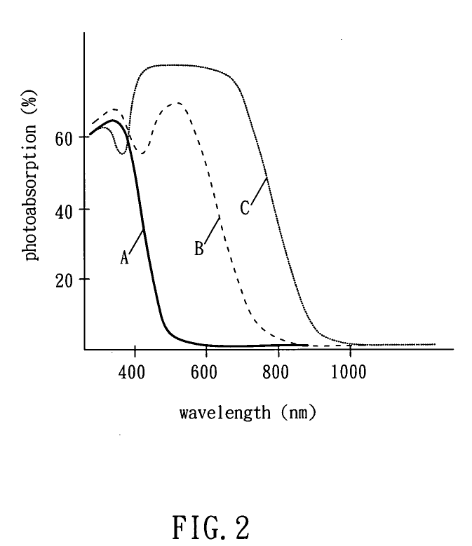

### DETAILED DESCRIPTION OF THE PREFERRED EMBODIMENT

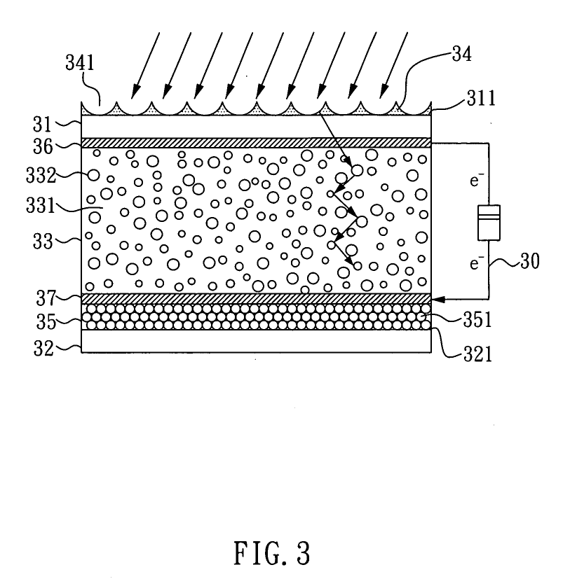

As shown in FIG. 3, there is shown a perspective view of a dye-sensitized solar cell in a first embodiment of the present invention, comprising: a first substrate 31, a second substrate 32, and a photoenergy conversion layer 33 disposed between the first substrate 31 and the second substrate 32. Herein, the photoenergy conversion layer 33 comprises an electrolytic condensed matter 331 and pluralities of dye-adsorbed units 332, and the dye-adsorbed units 332 are dispersed in the electrolytic condensed matter 331. In the first embodiment, the electrolytic condensed matter 331 of the photoenergy conversion layer 33 comprises pluralities of redox mediators, and the dye-adsorbed units 332 comprise pluralities of titanium oxide nanocapsules.

In addition, the dye-sensitized solar cell of the first embodiment is operated in coordination with an outer loop 30, and the first substrate 31 and the second substrate 32 electrically connect to the outer loop 30. Furthermore, in the dye-sensitized solar cell of the first embodiment, a first photonic crystal layer 34 is disposed on the surface 311 of the first substrate 31, and a second photonic crystal layer 35 is disposed on the surface 321 of the second substrate 32. Moreover, a first transparent conductor 36 is disposed on a side of the first substrate 31 adjacent to the photoenergy conversion layer 33, so that the first transparent conductor 36 and the first photonic crystal layer 34 are disposed on the two sides of the first substrate 31, respectively. The first transparent conductor 36 electrically connects to the aforementioned outer loop 30. The second transparent conductor 37 is disposed between the second photonic crystal layer 35 and the photoenergy conversion layer 33 and electrically connects to the aforementioned outer loop 30.

During the operation of the dye-sensitized solar cell of the first embodiment, a beam of light from the external environment passes through the first photonic crystal layer 34, the first substrate 31 and the first transparent conductor 36 in sequence to arrive in the photoenergy conversion layer 33. In the first embodiment, the first photonic crystal layer 34 can function as an anti-reflective layer and a dispersion layer, and thereby the aforementioned light can efficiently pass through the first photonic crystal layer 34. Besides, the photonic crystal structure has the effect of photo confinement and the second photonic crystal layer 35 can function as a reflective layer, so that the aforementioned light arriving in the photoenergy conversion layer 33 can be reflected from the second photonic crystal layer 35 and pass through the photoenergy conversion layer 33 many times. That is, the light is confined to the photoenergy conversion layer 33. Thereby, the photoenergy conversion layer 33 can thoroughly convert the photoenergy of the light that is confined to the photoenergy conversion layer 33 of the dye-sensitized solar cell of the first embodiment to electric energy. Accordingly, in comparison to a conventional dye-sensitized solar cell, the dye-sensitized solar cell of the present embodiment has higher optoelectronic conversion efficiency. The conversion mechanism from photoenergy to electric energy in the photoenergy conversion layer 33 is well known and thereby is not mentioned here.

In the dye-sensitized solar cell of the first embodiment, the structural sizes of the first and second photonic crystal layers can be modified by the selection of diameter size of the nanocapsules, and thereby the wavelength range of the light available for the first and second photonic crystal layers can be tuned. That is, in the dye-sensitized solar cell of the present embodiment, by the suitable selection of structural sizes of the first and second photonic crystal layers, the long-wavelengthed light can successfully arrive in the photoenergy conversion layer and is confined therein until the photoenergy of the light is thoroughly converted to electric energy.

As shown in FIG. 3, in the dye-sensitized solar cell of the first embodiment, the first substrate 31 and the second substrate 32 are made of glass, and the first transparent conductor 36 and the second transparent conductor 37 are made of indium tin oxide (ITO). In addition, the first photonic crystal layer 34 is formed on the surface 311 of the first substrate 31 by an etching process for definition of a nanocapsule array. The first photonic crystal layer 34 is a two-dimensional photonic crystal including pluralities of spherical hollow portions 341. The spherical hollow portions 341 are in the shape of a sphere. The material of the nanocapsules used in the above-mentioned etching process for definition of a nanocapsule array is polymethyl methacrylate (PMMA), and the detail steps of the etching process for definition of a nanocapsule array are detailed as follows.

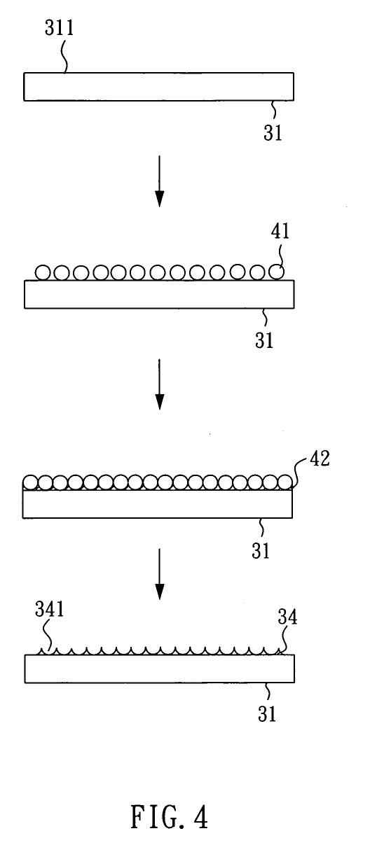

With reference to FIG. 4, a nanocapsule layer 41 including pluralities of nanocapsules is first formed on the surface 311 of the first substrate 31. The nanocapsules are made of polymethyl methacrylate (PMMA) and have an average diameter in the range of from 400 nm to 2000 nm. Subsequently, a silicon oxide (SiOx) layer 42 is formed on the partial surface of the first substrate 31 and in the gaps within the nanocapsule layer 41 by vapor deposition, and the first substrate 31 with the silicon oxide layer 42 thereon undergoes an annealing process at a temperature in the range of from 500° C. to 900° C.

After the completion of the annealing process, the first substrate 31 with the silicon oxide layer 42 thereon is soaked in formic acid (not shown in FIG. 4) to remove the aforementioned nanocapsules. Accordingly, a two-dimensional photonic crystal (i.e. the first photonic crystal layer 34) including pluralities of spherical hollow portions 341 is formed on the surface 311 of the first substrate 31. The suitable solution for removing the nanocapsules depends on the material of the nanocapsules. That is, the suitable solution for removing the nanocapsules made of silicon oxide is HF solution; and the suitable solution for removing the nanocapsules made of polystyrene is butanone or toluene.

As shown in FIG. 3, the second photonic crystal layer 35 includes pluralities of nanocapsule layers 351, and each of the nanocapsule layers 351 includes pluralities of nanocapsules. That is, the second photonic crystal layer 35 is formed by stacking pluralities of nanocapsules on the surface 321 of the second substrate 32, and the nanocapsules are made of silicon oxide. The process for stacking the nanocapsules on the surface 321 of the second substrate 32 is detailed as follows.

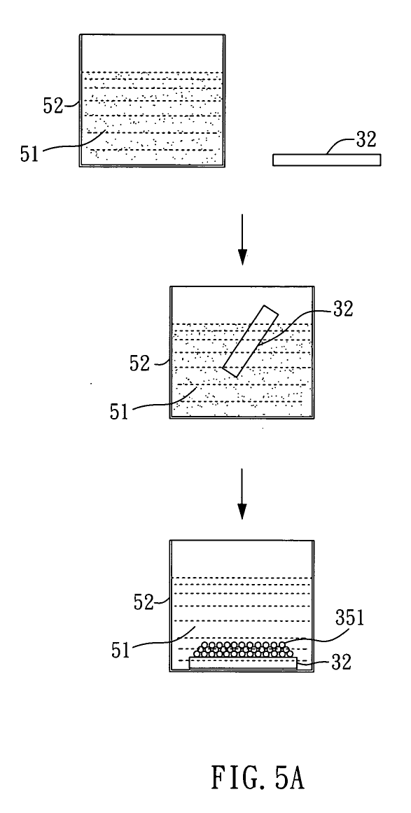

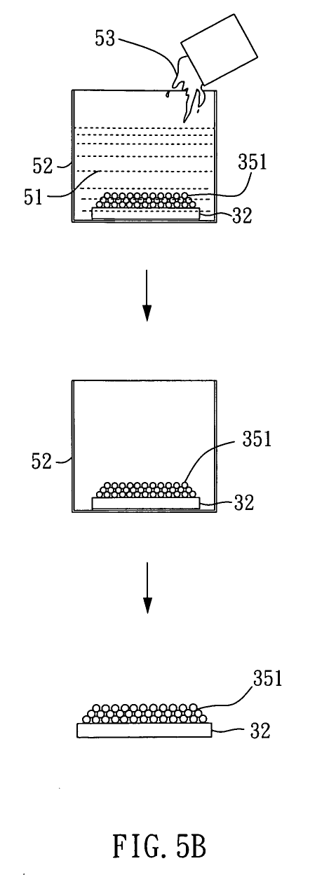

With reference to FIGS. 5A and 5B, a second substrate 32 and a colloidal solution 51 are first provided. The colloidal solution 51 includes pluralities of nanocapsules and a surfactant. Subsequently, the second substrate 32 is located in the container 52 filled with the colloidal solution 51 and soaked in the colloidal solution 51. After placed for several minutes, pluralities of nanocapsules gradually stack on the surface of the second substrate 32 to form pluralities of nanocapsule layers 351. Herein, the nanocapsules are made of silicon oxide and have an average diameter in the range of from 150 nm to 450 nm. However, the aforementioned process also can use polymethyl methacrylate, polystyrene, or titanium oxide as the material of the nanocapsules, and the size of the nanocapsules is not limited to the above-mentioned range. Then, the volatile acetone 53 is poured in the container 52 to evaporate the colloidal solution 51. After the colloidal solution 51 has evaporated, the second substrate 32 is taken out of the container 52 to obtain a second substrate 32 with pluralities of nanocapsule layers 351 thereon.

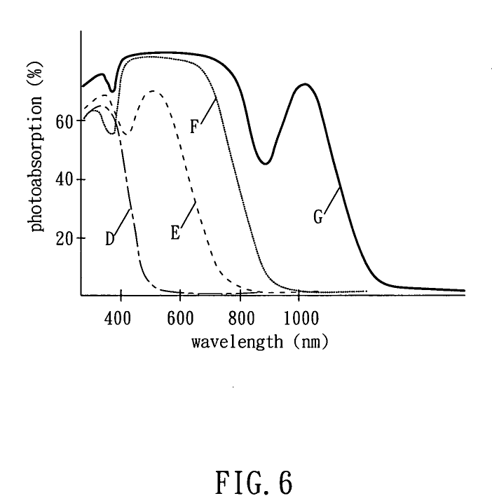

With reference to FIG. 6, there is shown a photoabsorption efficiency-wavelength diagram of each component in the dye-sensitized solar cell of the first embodiment. The curve D represents the correlation between photoabsorption efficiency of the titanium oxide nanocapsules in the photoenergy conversion layer and wavelength. The curve E represents the correlation between photoabsorption efficiency of the first dyestuff RuL₃ in the photoenergy conversion layer and wavelength. The curve F represents the correlation between photoabsorption efficiency of the second dyestuff RuL′(NCS)₃ in the photoenergy conversion layer and wavelength. The curve G represents the correlation between photoabsorption efficiency of the dye-sensitized solar cell including the first and second photonic crystal layers and wavelength.

As shown in FIG. 6, the dye-sensitized solar cell of the first embodiment can convert the photoenergy of the long-wavelengthed light (with wavelength larger than 800 nm), such as an infrared ray, to electric energy by the photonic crystal layers (such as the first and second photonic crystal layers) disposed therein. That is, the dye-sensitized solar cell of the first embodiment can absorb and employ the photoenergy of infrared ray that cannot be employed in a conventional dye-sensitized solar cell. Thereby, in the long-wavelength range, the dye-sensitized solar cell of the first embodiment has improved absorption efficiency and optoelectronic conversion efficiency in comparison to a conventional dye-sensitized solar cell.

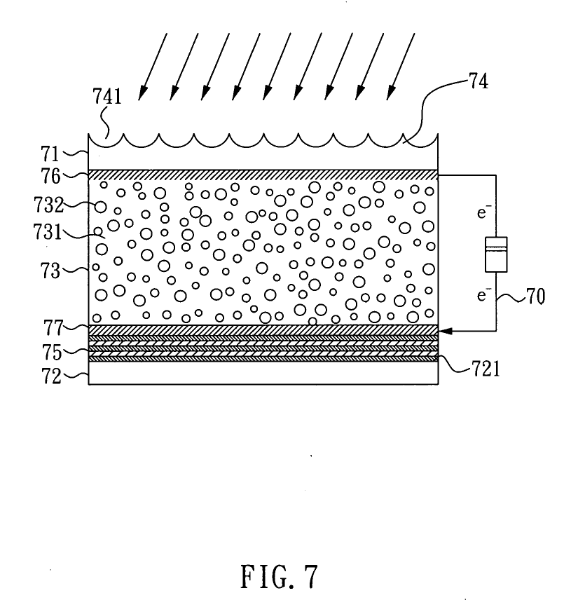

FIG. 7 shows a perspective view of a dye-sensitized solar cell in a second embodiment of the present invention, comprising: a first substrate 71, a second substrate 72, and a photoenergy-conversion layer 73 disposed between the first substrate 71 and the second substrate 72. Herein, the photoenergy conversion layer 73 comprises an electrolytic condensed matter 731 and pluralities of dye-adsorbed units 732, and the dye-adsorbed units 732 are dispersed in the electrolytic condensed matter 731. In addition, the dye-sensitized solar cell of the second embodiment is operated in coordination with an outer loop 70, and the first substrate 71 and the second substrate 72 electrically connect to the outer loop 70. Furthermore, in the dye-sensitized solar cell of the second embodiment, a first photonic crystal layer 74 is disposed on the surface of the first substrate 71, and a second photonic crystal layer 75 is disposed on the surface 721 of the second substrate 72. Moreover, a first transparent conductor 76 is disposed on a side of the first substrate 71 adjacent to the photoenergy conversion layer 73, so that the first transparent conductor 76 and the first photonic crystal layer 74 are disposed on the two sides of the first substrate 71, respectively. The first transparent conductor 76 electrically connects to the aforementioned outer loop 70. The second transparent conductor 77 is disposed between the second photonic crystal layer 75 and the photoenergy conversion layer 73 and electrically connects to the aforementioned outer loop 70.

As shown in FIG. 7, in the dye-sensitized solar cell of the second embodiment, the first substrate 71 and the second substrate 72 are made of polyethylene terephthalate, and the first transparent conductor 76 and the second transparent conductor 77 are made of indium tin oxide (ITO). In addition, the first photonic crystal layer 74 is formed on the surface of the first substrate 71 by a nano-imprinting process. The first photonic crystal layer 74 is a two-dimensional photonic crystal including pluralities of spherical hollow portions 741. The spherical hollow portions 741 are in the shape of a sphere and integrated with the first substrate 71. The second photonic crystal layer 75 functions as a distributed Bragg reflector.

During the operation of the dye-sensitized solar cell of the second embodiment, a beam of light from the external environment passes through the first photonic crystal layer 74, the first substrate 71 and the first transparent conductor 76 in sequence to arrive in the photoenergy conversion layer 73 and is reflected from the second photonic crystal layer 75 to pass through the photoenergy conversion layer 73 many times and be confined therein. Accordingly, in comparison to a conventional dye-sensitized solar cell, the dye-sensitized solar cell of the second embodiment has higher optoelectronic conversion efficiency.

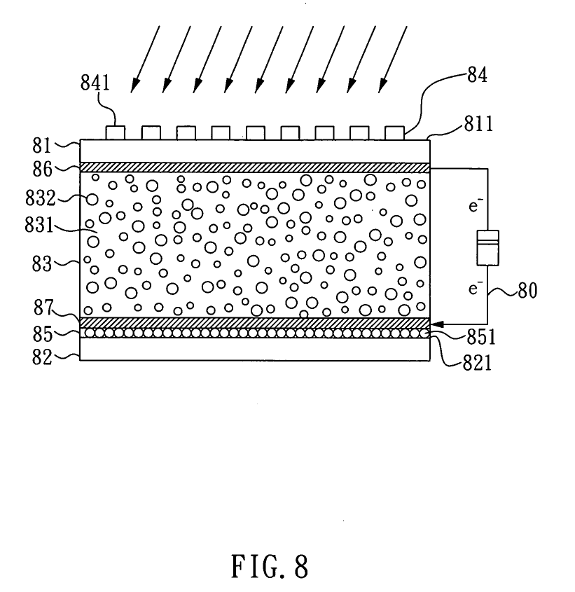

FIG. 8 shows a perspective view of a dye-sensitized solar cell in a third embodiment of the present invention, comprising: a first substrate 81, a second substrate 82, and a photoenergy conversion layer 83 disposed between the first substrate 81 and the second substrate 82. Herein, the photoenergy conversion layer 83 comprises an electrolytic condensed matter 831 and pluralities of dye-adsorbed units 832, and the dye-adsorbed units 832 are dispersed in the electrolytic condensed matter 831. In addition, the dye-sensitized solar cell of the third embodiment is operated in coordination with an outer loop 80, and the first substrate 81 and the second substrate 82 electrically connect to the outer loop 80. Furthermore, in the dye-sensitized solar cell of the third embodiment, a first photonic crystal layer 84 is disposed on the surface 811 of the first substrate 81, and a second photonic crystal layer 85 is disposed on the surface 821 of the second substrate 82. Moreover, a first transparent conductor 86 is disposed on a side of the first substrate 81 adjacent to the photoenergy conversion layer 83, so that the first transparent conductor 86 and the first photonic crystal layer 84 are disposed on the two sides of the first substrate 81, respectively. The first transparent conductor 86 electrically connects to the aforementioned outer loop 80. The second transparent conductor 87 is disposed between the second photonic crystal layer 85 and the photoenergy conversion layer 83 and electrically connects to the aforementioned outer loop 80.

As shown in FIG. 8, in the dye-sensitized solar cell of the third embodiment, the first substrate 81 and the second substrate 82 are made of glass, and the first transparent conductor 86 and the second transparent conductor 87 are made of indium tin oxide (ITO). In addition, the first photonic crystal layer 84 is formed on the surface 811 of the first substrate 81 by a photographic process to be a two-dimensional photonic crystal consisting of plural photoresist units 841. The second photonic crystal layer 85 comprises a nanocapsule layer 851 including pluralities of nanocapsules, and the nanocapsules are made of silicon oxide.

During the operation of the dye-sensitized solar cell of the third embodiment, a beam of light from the external environment passes through the first photonic crystal layer 84, the first substrate 81 and the first transparent conductor 86 in sequence to arrive in the photoenergy conversion layer 83 and is reflected from the second photonic crystal layer 85 to pass through the photoenergy conversion layer 83 many times and be confined therein. Accordingly, in comparison to a conventional dye-sensitized solar cell, the dye-sensitized solar cell of the third embodiment has higher optoelectronic conversion efficiency.

All in all, the dye-sensitized solar cell of the present invention can convert the photoenergy of the long-wavelengthed light to electric energy by the photonic crystal layers (such as the first and second photonic crystal layers) disposed therein. That is, the dye-sensitized solar cell of the present invention can efficiently employ the light that cannot be employed in a conventional dye-sensitized solar cell, such as an infrared ray. Thereby, in the long-wavelength range, the dye-sensitized solar cell of the present invention has improved absorption efficiency and optoelectronic conversion efficiency so as to replace a current silicon solar cell and be a most favored technique in the green energy industries.

Although the present invention has been explained in relation to its preferred embodiment, it is to be understood that many other possible modifications and variations can be made without departing from the scope of the invention as hereinafter claimed.

What is claimed is:

1. A dye-sensitized solar cell, in coordination with an outer loop, comprising:
a first substrate;
a second substrate; and
a photoenergy conversion layer, disposed between the first substrate and the second substrate and comprising an electrolytic condensed matter and pluralities of dye-adsorbed units dispersed in the electrolytic condensed matter;
wherein, a first photonic crystal layer is disposed on the surface of the first substrate, a beam of light from the external environment passes through the first photonic crystal layer and the first substrate to arrive in the photoenergy conversion layer, the photoenergy conversion layer converts photoenergy of the light to electric energy, and the outer loop electrically connects to the first substrate and the second substrate.

2. The dye-sensitized solar cell as claimed in claim 1, further comprising a first transparent conductor disposed on one side of the first substrate adjacent to the photoenergy conversion layer, wherein the first transparent conductor and the first photonic crystal layer are disposed on the two sides of the first substrate, and the first transparent conductor electrically connects to the outer loop.

3. The dye-sensitized solar cell as claimed in claim 1, wherein the first substrate is disposed between the first photonic crystal layer and the photoenergy conversion layer.

4. The dye-sensitized solar cell as claimed in claim 1, further comprising a second transparent conductor disposed on one side of the second substrate adjacent to the photoenergy conversion layer, and the second transparent conductor electrically connects to the outer loop.

5. The dye-sensitized solar cell as claimed in claim 1, further comprising a second photonic crystal layer disposed on the surface of the second substrate.

6. The dye-sensitized solar cell as claimed in claim 5, wherein the second photonic crystal layer is disposed on the surface of the second substrate adjacent to the photoenergy conversion layer.

7. The dye-sensitized solar cell as claimed in claim 5, further comprising a second transparent conductor disposed between the second photonic crystal layer and the photoenergy conversion layer and electrically connecting to the outer loop.

8. The dye-sensitized solar cell as claimed in claim 1, wherein the first photonic crystal layer is formed on the surface of the first substrate by an etching process for definition of a nanocapsule array.

9. The dye-sensitized solar cell as claimed in claim 8, wherein the etching process for definition of a nanocapsule array uses nanocapsules made of silicon oxide.

10. The dye-sensitized solar cell as claimed in claim 1, wherein the first photonic crystal layer comprises pluralities of spherical hollow portions.

11. The dye-sensitized solar cell as claimed in claim 10, wherein the spherical hollow portions are in the shape of a sphere.

12. The dye-sensitized solar cell as claimed in claim 1, wherein the first photonic crystal layer comprises pluralities of photoresist units.

13. The dye-sensitized solar cell as claimed in claim 1, wherein the first photonic crystal layer functions as an anti-reflective layer.

14. The dye-sensitized solar cell as claimed in claim 5, wherein the second photonic crystal layer comprises at least one nanocapsule layer, and the nanocapsule layer comprises pluralities of nanocapsules.

15. The dye-sensitized solar cell as claimed in claim 14, wherein the nanocapsules are made of silicon oxide.

16. The dye-sensitized solar cell as claimed in claim 5, wherein the second photonic crystal layer is a distributed Bragg reflector.

17. The dye-sensitized solar cell as claimed in claim 5, wherein the second photonic crystal layer is a reflective layer.

18. The dye-sensitized solar cell as claimed in claim 1, wherein the first substrate and the second substrate are made of polyethylene terephthalate.

19. The dye-sensitized solar cell as claimed in claim 1, wherein the first substrate and the second substrate are made of glass.

20. The dye-sensitized solar cell as claimed in claim 2, wherein the first transparent conductor is made of indium tin oxide.

21. The dye-sensitized solar cell as claimed in claim 4, wherein the second transparent conductor is made of indium tin oxide.

22. The dye-sensitized solar cell as claimed in claim 7, wherein the second transparent conductor is made of indium tin oxide

23. The dye-sensitized solar cell as claimed in claim 1, wherein the electrolytic condensed matter comprises pluralities of redox mediators.

24. The dye-sensitized solar cell as claimed in claim 1, wherein the dye-adsorbed units comprise pluralities of titanium oxide nanocapsules.
